(19) United States
(12) Patent Application Publication
(10) Pub. No.: US 2014/0361790 A1
(43) Pub. Date: Dec. 11, 2014

(54) DRIVE CIRCUIT, SWITCH APPARATUS, AND TEST APPARATUS

(71) Applicant: ADVANTEST CORPORATION, Tokyo (JP)

(72) Inventors: Makoto NAKANISHI, Tokyo (JP); Yoshiyuki HATA, Tokyo (JP); Masahiko TAKIKAWA, Tokyo (JP)

(73) Assignee: ADVANTEST CORPORATION, Tokyo (JP)

(21) Appl. No.: 13/914,649

(22) Filed: Jun. 11, 2013

(51) Int. Cl. H02J 1/00; G01R 1/20

(52) U.S. Cl. CPC H02J 1/00; G01R 1/206
USPC 324/555; 307/24

(57) ABSTRACT

Provided is a test apparatus, a switch apparatus, and a drive circuit comprising a current source having one end thereof connected to a reference potential; a first switch connected between the current source and a first voltage source that outputs a first power supply voltage; a first output terminal that outputs a voltage between the first switch and the first voltage source; a power supply section that outputs a second power supply voltage when the first switch is ON and outputs a third power supply voltage, which is lower than the second power supply voltage, when the first switch is OFF; a second switch connected between the power supply section and the current source; and a second output terminal that outputs a voltage between the second switch and the power supply section.

### BACKGROUND

1. Technical Field

The present invention relates to a drive circuit, a switch apparatus, and a test apparatus.

2. Related Art

Conventionally, a drive circuit that supplies a drive signal for turning a semiconductor switch such as a FET (Field Effect Transistor) ON and OFF is formed using a semiconductor circuit, such as shown in Patent Document 1, for example.
Patent Document 1: Japanese Patent Application Publication No. 2003-318722

However, when the potential difference between the gate-source voltage for turning on the FET and the gate-source voltage for turning OFF the FET is made large in order to decrease the leak current, the resulting drive circuit has a complex configuration and it is difficult to realize a drive circuit having a simple configuration that operates at high speed and with low power consumption. When configuring a circuit using a plurality of types of FETs, manufacturing variations in the characteristics among the semiconductor elements must be considered during the design phase, thereby making it difficult to form the drive circuit.

### SUMMARY

Therefore, it is an object of an aspect of the innovations herein to provide a drive circuit, a switch apparatus, and a test apparatus, which are capable of overcoming the above drawbacks accompanying the related art. The above and other objects can be achieved by combinations described in the claims. According to a first aspect of the present invention, provided is a test apparatus, a switch apparatus, and a drive circuit comprising a current source having one end thereof connected to a reference potential; a first switch connected between the current source and a first voltage source that outputs a first power supply voltage; a first output terminal that outputs a voltage between the first switch and the first voltage source; a power supply section that outputs a second power supply voltage when the first switch is ON and outputs a third power supply voltage, which is lower than the second power supply voltage, when the first switch is OFF; a second switch connected between the power supply section and the current source; and a second output terminal that outputs a voltage between the second switch and the power supply section.

The summary clause does not necessarily describe all necessary features of the embodiments of the present invention. The present invention may also be a sub-combination of the features described above.

### BRIEF DESCRIPTION OF THE DRAWINGS

FIG. 1 shows a configuration of a switch apparatus 100 according to an embodiment of the present invention, along with a control section 110.

FIG. 2 shows an exemplary configuration of a SCFL circuit 20.

FIG. 3 shows an exemplary configuration of the switch apparatus 100 according to the present embodiment, along with the control section 110.

FIG. 4 shows a configuration of a modification of the switch apparatus 100 according to the present embodiment, along with the control section 110.

FIG. 5 shows an exemplary configuration of a test apparatus 500 according to the present embodiment, along with a device under test 400.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

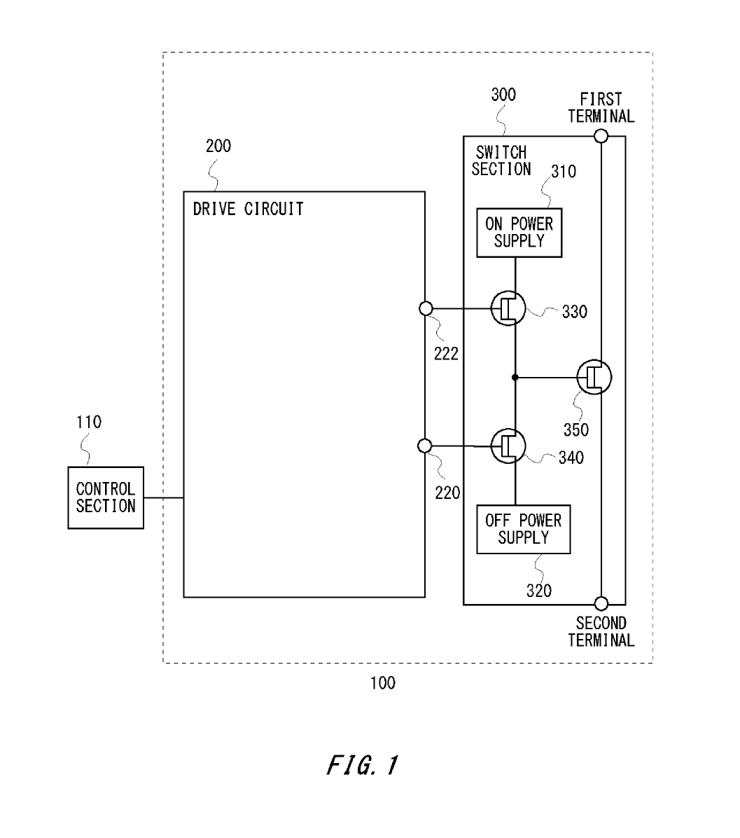

FIG. 1 shows a configuration of a switch apparatus 100 according to an embodiment of the present invention, along with a control section 110. The switch apparatus 100 includes a drive circuit 200 and a switch section 300. The switch apparatus 100 switches an electrical connection between a first terminal and a second terminal of a switch section 300 to be ON (connected) or OFF (disconnected), according to a drive signal output by the drive circuit 200.

The control section 110 transmits a control signal to the drive circuit 200. The control section 110 may transmit a plurality of control signals, and may also supply the drive circuit 200 with a power supply voltage.

The drive circuit 200 is connected to the control section 110 and outputs a drive signal according to a control signal received from the control section 110. Here, the drive signal may include a first drive signal and a second drive signal, for example. The drive circuit 200 includes a first output terminal 220 and a second output terminal 222. The drive circuit 200 outputs, to the switch section 300, the first drive signal from the first output terminal 220 and the second drive signal from the second output terminal 222.

The switch section 300 electrically connects (ON) or disconnects (OFF) that first terminal and the second terminal, according to the drive signal received from the drive circuit 200. The switch section 300 includes an ON power supply 310, an OFF power supply 320, an ON switch 330, an OFF switch 340, and a main switch 350.

The ON power supply 310 supplies an ON voltage for turning ON the main switch 350. The ON power supply 310 is a constant voltage supply that outputs a predetermined voltage, for example. The OFF power supply 320 supplies an OFF voltage for turning OFF the main switch 350. The OFF power supply 320 is a constant voltage supply that outputs a predetermined voltage, for example. In the switch section 300 of the present embodiment, the ON voltage is 0 V and the OFF voltage is −10 V.

The ON switch 330 switches whether the ON voltage from the ON power supply 310 is supplied to the gate of the main switch 350. The ON switch 330 is an n-type depletion FET that is electrically connected between the gate of the main switch 350 and the ON power supply 310 for turning ON the main switch 350 and supplies the gate with the second drive signal, for example.

In this case, the gate of the ON switch 330 is connected to the second output terminal 222 of the drive circuit 200, the source of the ON switch 330 is connected to the ON power supply 310, and the drain of the ON switch 330 is connected to the gate of the main switch 350. In other words, the gate of the ON switch 330 is supplied with the second drive signal output from the drive circuit 200.

The OFF switch 340 switches whether the OFF voltage of the OFF power supply 320 is supplied to the gate of the main switch 350. The OFF switch 340 is an n-type depletion FET that is electrically connected between the gate of the main switch 350 and the OFF power supply 320 for turning OFF the main switch 350 and supplies the gate with the first drive signal, for example.

In this case, the gate of the OFF switch 340 is connected to the first output terminal 220 of the drive circuit 200, the source of the OFF switch 340 is connected to the OFF power supply 320, and the drain of the OFF switch 340 is connected to the gate of the main switch 350. In other words, the gate of the OFF switch 340 is supplied with the first drive signal output from the drive circuit 200.

The main switch 350 is turned ON and OFF according to the first drive signal output from the first output terminal 220 and the second drive signal output from the second output terminal 222 of the drive circuit 200. The main switch 350 is provided between the first terminal and the second terminal, is electrically connected between the first terminal and the second terminal when in the ON state, and is electrically isolated when in the OFF state.

The source of the main switch 350 is connected to the first terminal and the drain of the main switch 350 is connected to the second terminal. The present embodiment describes an example in which the main switch 350 is an N-channel depletion normally-ON FET that is ON when the gate-source voltage is substantially 0 V. Furthermore, the main switch 350 is a FET in which current begins to flow when the gate-source voltage is approximately −3 V.

In other words, the main switch 350 begins turning ON by supplying a gate-source voltage thereto that is greater than or equal to a predetermined gate-source voltage, i.e. a threshold voltage Vth, and is turned OFF by supplying a gate-source voltage that is less than the threshold voltage Vth. The present embodiment describes an example in which the threshold voltage Vth is −3 V.

In the switch apparatus 100 of the present embodiment, when turning ON the main switch 350, the drive circuit 200 outputs a first drive signal and a second drive signal for turning ON the ON switch 330 and turning OFF the OFF switch 340. In this way, the switch apparatus 100 can supply the ON voltage from the ON power supply 310 to the gate of the main switch 350.

In the switch apparatus 100 of the present embodiment, when turning OFF the main switch 350, the drive circuit 200 outputs a first drive signal and a second drive signal for turning OFF the ON switch 330 and turning ON the OFF switch 340. In this way, the switch apparatus 100 can supply the OFF voltage from the OFF power supply 320 to the gate of the main switch 350. The switch apparatus 100 of the present embodiment can switch between the ON state and the OFF state by setting the potential difference between the ON voltage and the OFF voltage of the gate voltage for switching the main switch 350 ON and OFF to be substantially 10 V or more.

The switch apparatus 100 outputs from the drive circuit 200 the first drive signal and the second drive signal that determine the operation of the ON switch 330 and the OFF switch 340 connected between the ON power supply 310 and the OFF power supply 320, in order to turn the main switch 350 ON and OFF. Here, a case is described in which the ON switch 330 and the OFF switch 340 are practically the same type of FETs as the main switch 350. In other words, the ON switch 330, the OFF switch 340, and the main switch 350 are formed with substantially the same configuration such that these switches are turned ON by supplying a gate-source voltage of −3 V or more, which is an example of the threshold voltage Vth in the present embodiment, and are turned OFF by supplying a gate-source voltage of less than −3 V.

In this case, the drive circuit 200 can set the ON state by supplying 0 V to the gate of the ON switch 330 to set the gate-source voltage of the ON switch 330 at 0 V, for example. Furthermore, in this case, the drive circuit 200 can turn ON the ON switch 330 and turn OFF the OFF switch 340 by supplying −15 V to the gate of the OFF switch 340 to set the gate-source voltage of the OFF switch 340 at −5 V.

In the same manner, the drive circuit 200 can set ON state by supplying −10 V to the gate of the OFF switch 340 to set the gate-source voltage of the OFF switch 340 at 0 V. In this case, since the OFF voltage of the OFF power supply 320 is supplied to the gate of the main switch 350, even if the drive circuit 200 supplies −5 V to the gate of the ON switch 330, the potential difference between the gate of the ON switch 330 and the gate of the main switch 350 is +5 V, and therefore the ON switch 330 cannot be set to the OFF state.

In this case, the source and drain of the ON switch 330 are switched, and therefore the drive circuit 200 can set the gate-source voltage of the ON switch 330 to be −5 V by supplying −15 V to the gate of the ON switch 330. In this way, the drive circuit 200 can turn ON the OFF switch 340 and turn OFF the ON switch 330 by setting the first drive signal to substantially −10 V and the second drive signal to substantially −15 V.

Accordingly, in order to switch the main switch 350 ON and OFF, the drive circuit 200 must output to the switch section 300 a first drive signal that switches between substantially −15 V and substantially −10 V and a second drive signal that switches between substantially 0 V and substantially −15 V. An SCFL (Source Coupled FET Logic) circuit is known as a drive circuit that outputs such a drive signal.

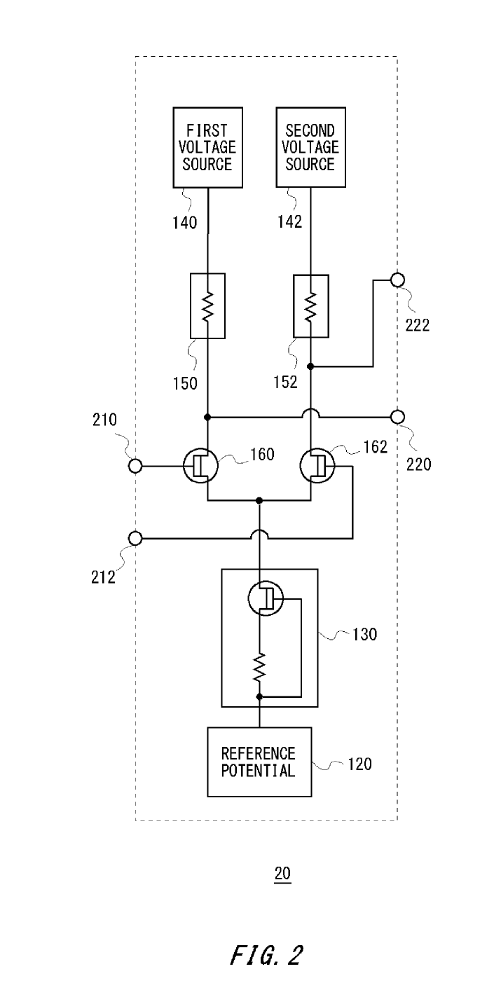

FIG. 2 shows an exemplary configuration of an SCFL circuit 20. The SCFL circuit 20 includes a reference potential 120, a current source 130, a first voltage source 140, a second voltage source 142, a first resistor 150, a second resistor 152, a first switch 160, a second switch 162, a first input terminal 210, a second input terminal 212, a first output terminal 220, and a second output terminal 222.

The reference potential 120 outputs a predetermined reference potential. The reference potential 120 is a voltage supply that outputs a predetermined voltage, for example. FIG. 2 describes an example in which the reference potential output by the reference potential 120 is −30 V.

The current source 130 has one end that is connected to the reference potential 120, and a prescribed current flows from the other end to the one end. The current source 130 includes a FET and a resistor, and functions as a constant current source, for example. FIG. 2 describes an example of a current source 130 that is a constant current circuit in which one end of the resistor is connected to the source of the FET, the other end of the resistor is connected to the gate of the FET, and a current of 100 μA flows from the drain of the FET to the reference potential 120.

The first voltage source 140 outputs a predetermined first power supply voltage. The second voltage source 142 outputs a second power supply voltage. FIG. 2 describes an example in which the first power supply voltage is −10 V and the second power supply voltage is 0 V.

The first resistor 150 is a resistance element having one end that is connected to the first voltage source 140. The first resistor 150 causes a shift from the first power supply voltage by a voltage value obtained as the product of the resistance value of the first resistor 150 and the magnitude of the current flowing through the first resistor 150. FIG. 2 describes an example in which, when the first resistor 150 is 50 kΩ and a current of 100 μA flows through the first resistor 150, there is a shift of 5 V from the first power supply voltage of −10 V.

The second resistor 152 is a resistance element having one end that is connected to the second voltage source 142. The second resistor 152 causes a shift from the second power supply voltage by a voltage value obtained as the product of the resistance value of the second resistor 152 and the magnitude of the current flowing through the second resistor 152. FIG. 2 describes an example in which, when the second resistor 152 is 150 kΩ and a current of 100 μA flows through the second resistor 152, there is a shift of 15 V from the second power supply voltage of 0 V.

The first switch 160 is connected between the other end of the current source 130 and the other end of the first resistor 150. The first switch 160 switches the electrical connection between the current source 130 and the first resistor 150 to be ON (connected) or OFF (disconnected), according to the control signal from the control section 110. FIG. 2 describes an example in which the first switch 160 is a FET in which the gate is connected to the control section 110, the drain is connected to the other end of the current source 130, and the source is connected to the other end of the first resistor 150.

The second switch 162 is connected between the other end of the current source 130 and the other end of the second resistor 152. The second switch 162 switches the electrical connection between the current source 130 and the second resistor 152 to be ON (connected) or OFF (disconnected), according to the control signal from the control section 110. FIG. 2 describes an example in which the second switch 162 is a FET in which the gate is connected to the control section 110, the drain is connected to the other end of the current source 130, and the source is connected to the other end of the second resistor 152.

Here, the first switch 160 and the second switch 162 may be n-type depletion FETs, for example. Furthermore, an example is described in which the FET of the current source 130, the first switch 160, and the second switch 162 are practically the same type of FET as the main switch 350. In other words, the FET of the current source 130, the first switch 160, the second switch 162, the ON switch 330, the OFF switch 340, and the main switch 350 are formed with substantially the same configuration such that these switches are turned ON by supplying a gate-source voltage of −3 V or more, which is an example of the threshold voltage Vth in the present embodiment, and are turned OFF by supplying a gate-source voltage of less than −3 V.

The first input terminal 210 is connected to the first switch 160, and the second input terminal 212 is connected to the second switch 162. FIG. 2 shows an example in which the first input terminal 210 is connected to the gate of the first switch 160 and the second input terminal 212 is connected to the gate of the second switch 162.

The first output terminal 220 is connected between the first switch 160 and the first resistor 150, and outputs the voltage between the first switch 160 and the first resistor 150. The second output terminal 222 is connected between the second switch 162 and the second resistor 152, and outputs the voltage between the second switch 162 and the second resistor 152.

When turning ON the main switch 350, the SCFL circuit 20 described above turns ON the first switch 160 and turns OFF the second switch 162. In this way, a circuit from the first voltage source 140 to the reference potential 120 is connected, and a constant current of 100 μA flows through this circuit. Accordingly, the first output terminal 220 outputs a first drive signal of −15 V, obtained by a shift of 5 V from the first power supply voltage. On the other hand, the second output terminal 222 outputs a second drive signal of 0 V, since the second switch 162 is OFF.

Furthermore, when turning OFF the main switch 350, the SCFL circuit 20 turns OFF the first switch 160 and turns ON the second switch 162. In this way, a circuit from the second voltage source 142 to the reference potential 120 is connected, and a constant current of 100 μA flows through this circuit. Accordingly, the second output terminal 222 outputs a second drive signal of −15 V, obtained by a shift of 15 V from the second power supply voltage. On the other hand, the first output terminal 220 outputs a first drive signal of −10 V, since the first switch 160 is OFF.

In this way, the SCFL circuit 20 can supply the switch section 300 with a first drive signal that switches between substantially −15 V and substantially −10 V and a second drive signal that switches between substantially 0 V and substantially −15 V. Furthermore, by switching the first switch 160 ON and OFF and switching the second switch 162 OFF and ON, the SCFL circuit 20 can output the first drive signal and the second drive signal. In other words, the control section 110 can output the first drive signal and the second drive signal from the SCFL circuit 20 by supplying the first switch 160 and the second switch 162 respectively with control signals having a potential difference of substantially 3 V or more therebetween.

The control section 110 may supply the first input terminal 210 with a control signal of substantially −16.5 V as the ON voltage for turning the first switch 160 ON and a control signal of substantially −19.5 V as the OFF voltage for turning OFF the first switch 160. The control section 110 may supply the second input terminal 212 with a control signal of substantially −16.5 V as the ON voltage for turning the second switch 162 ON and a control signal of substantially −19.5 V as the OFF voltage for turning OFF the first switch 160.

In the above description, the SCFL circuit 20 can supply the switch section 300 with the first drive signal and the second drive signal according to the control signal of the control section 110. However, since the current source 130 always provides a constant current regardless of the magnitude of the voltage of the drive signal, the SCFL circuit 20 might have large power consumption. For example, in FIG. 2, a current of 100 μA flows through the first resistor 150 of 50 kΩ when the first switch 160 is ON and a current of 100 μA flows through the second resistor 152 of 150 kΩ when the second switch 162 is ON, and therefore there is a difference of a factor of three in the power consumption.

In other words, the SCFL circuit 20 includes the first resistor 150 and the second resistor 152 with resistance values corresponding to the potential difference of the drive signal, and a voltage is determined in advance that drops at these resistance values. Accordingly, as shown in the example of FIG. 2, the SCFL circuit 20 increases the magnitude of the voltage drop caused by the second resistor 152 to switch the absolute value of the potential difference between the first drive signal and the second drive signal from 15 V to 5 V, thereby increasing the power consumption. The drive circuit 200 of the present embodiment provides the switch section 300 with the first drive signal and the second drive signal while stopping this increase in power consumption.

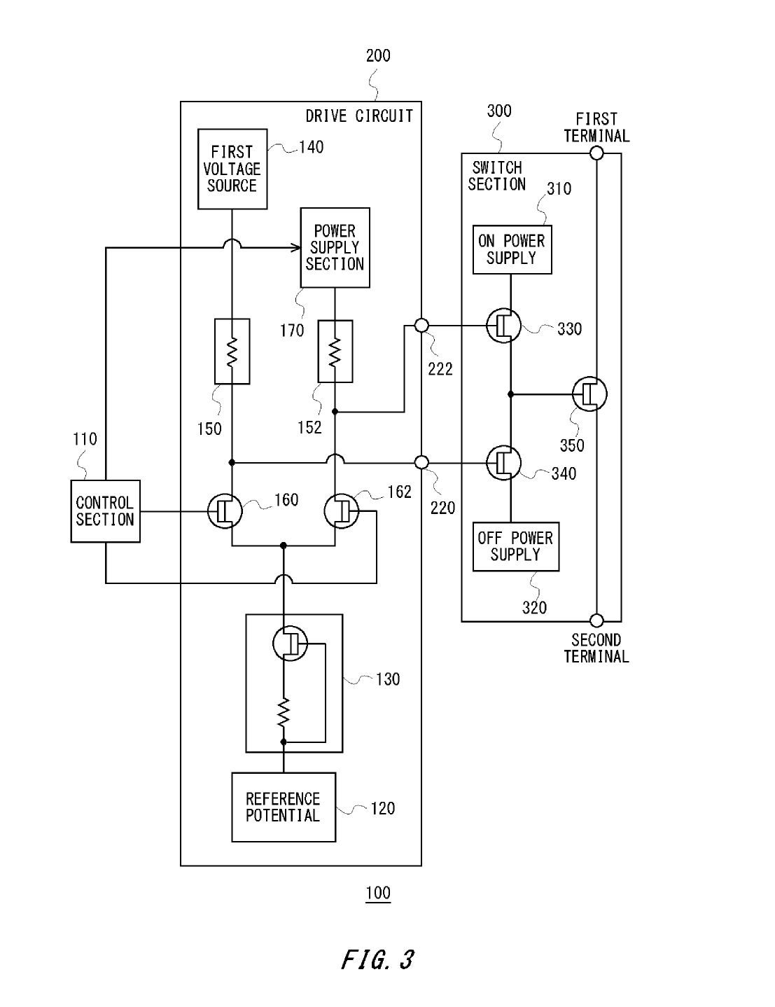

FIG. 3 shows an exemplary configuration of the switch apparatus 100 according to the present embodiment, along with the control section 110. The switch apparatus 100 switches the power supply voltage of the drive circuit 200 according to the voltage of the drive signal and stops the increase in power consumption. In the switch apparatus 100 of the present embodiment, components that have substantially the same operation as components in the switch apparatus 100 shown in FIG. 1 are given the same reference numerals and redundant descriptions are omitted. The drive circuit 200 of the switch apparatus 100 includes a reference potential 120, a current source 130, a first voltage source 140, a first resistor 150, a second resistor 152, a first switch 160, a second switch 162, and a power supply section 170.

The reference potential 120 outputs a predetermined reference potential. The reference potential 120 may be a voltage supply that outputs a predetermined voltage, for example. FIG. 3 describes an example in which the reference potential output by the reference potential 120 is −30 V.

The current source 130 has one end that is connected to the reference potential 120, and a prescribed current flows from the other end to the one end. The current source 130 includes a FET and a resistor, and functions as a constant current source, for example. FIG. 3 describes an example of a current source 130 that is a constant current circuit in which one end of the resistor is connected to the source of the FET, the other end of the resistor is connected to the gate of the FET, and a current of 100 μA flows from the drain of the FET to the reference potential 120.

The first voltage source 140 outputs a predetermined first power supply voltage. FIG. 3 describes an example in which the first power supply voltage is −10 V. The first switch 160 is connected between the current source 130 and the first voltage source 140. The second switch 162 is connected between the current source 130 and the power supply section 170.

The first resistor 150 is connected between the first voltage source 140 and the first switch 160. The first resistor 150 is a resistance element having one end that is connected to the first voltage source 140. The first resistor 150 causes a shift from the first power supply voltage by a voltage value obtained as the product of the resistance value of the first resistor 150 and the magnitude of the current flowing through the first resistor 150. FIG. 3 describes an example in which, when the first resistor 150 is 50 kΩ and a current of 100 μA flows through the first resistor 150, there is a shift of 5 V from the −10 V of the first power supply voltage.

The second resistor 152 is connected between the power supply section 170 and the second switch 162. The second resistor 152 is a resistance element having one end that is connected to the power supply section 170. The second resistor 152 causes a shift from the output voltage of the power supply section 170 by a voltage value obtained as the product of the resistance value of the second resistor 152 and the magnitude of the current flowing through the second resistor 152. FIG. 3 describes an example in which, when the second resistor 152 is 80 kΩ and a current of 100 μA flows through the second resistor 152, there is a shift of 8 V from the output voltage of the power supply section 170.

The first switch 160 is connected between the other end of the current source 130 and the other end of the first resistor 150. The first switch 160 switches the electrical connection between the current source 130 and the first resistor 150 to be ON or OFF, according to the control signal from the control section 110. FIG. 3 describes an example in which the first switch 160 is a FET in which the gate is connected to the control section 110, the drain is connected to the other end of the current source 130, and the source is connected to the other end of the first resistor 150.

The second switch 162 is connected between the current source 130 and the power supply section 170. More specifically, the second switch 162 is connected between the other end of the current source 130 and the other end of the second resistor 152. The second switch 162 switches the electrical connection between the current source 130 and the second resistor 152 to be ON or OFF, according to the control signal from the control section 110. FIG. 3 describes an example in which the second switch 162 is a FET in which the gate is connected to the control section 110, the drain is connected to the other end of the current source 130, and the source is connected to the other end of the second resistor 152.

Here, the FET of the current source 130, the first switch 160, and the second switch 162 may be n-type depletion FETs, for example. Furthermore, an example is described in which the FET of the current source 130, the first switch 160, and the second switch 162 are practically the same type of FET as the main switch 350.

In other words, the FET of the current source 130, the first switch 160, the second switch 162, the ON switch 330, the OFF switch 340, and the main switch 350 are formed with substantially the same configuration such that these switches are turned ON by supplying a gate-source voltage greater than or equal to the threshold voltage Vth and are turned OFF by supplying a gate-source voltage of less than the threshold voltage Vth. The present embodiment describes an example in which the threshold voltage Vth is −3 V.

The power supply section 170 outputs a second power supply voltage when the first switch 160 is ON, and outputs a third power supply voltage that is less than the second power supply voltage when the first switch 160 is OFF. Furthermore, the power supply section 170 outputs, as the second power supply voltage, a voltage that is higher than the first power supply voltage. Here, the power supply section 170 may output, as the third power supply voltage, a voltage greater than or equal to the first power supply voltage. FIG. 3 describes an example in which the power supply section 170 outputs 0 V as the second power supply voltage and −7 V as the third power supply voltage.

The power supply section 170 of the present embodiment is connected to the control section 110 and switches between the second power supply voltage and the third power supply voltage according to the control signal from the control section 110. Specifically, the control section 110 transmits to the drive circuit 200 a control signal that turns ON the first switch 160 and turns OFF the second switch 162, together with a control signal that causes the second power supply voltage to be output from the power supply section 170. Furthermore, the control section 110 transmits to the drive circuit 200 a control signal that turns OFF the first switch 160 and turns ON the second switch 162, together with a control signal that causes the third power supply voltage to be output from the power supply section 170.

The first output terminal 220 is connected between the first switch 160 and the first resistor 150, and outputs the voltage between the first switch 160 and the first resistor 150. The second output terminal 222 is connected between the second switch 162 and the power supply section 170, more specifically between the second switch 162 and the second resistor 152, and outputs the voltage between the second switch 162 and the second resistor 152.

With the drive circuit 200 described above, the first output terminal 220 outputs the first power supply voltage from the first voltage source 140 when the first switch 160 is OFF and, when the first switch 160 is ON, outputs a voltage obtained by subtracting a drop voltage determined by the first resistor 150 and the current flowing through the current source 130 from the first power supply voltage. Furthermore, the second output terminal 222 outputs the second power supply voltage when the second switch 162 is OFF and, when the second switch 162 is ON, outputs a voltage obtained by subtracting a drop voltage determined by the second resistor 152 and the current flowing through the current source 130 from the third power supply voltage.

For example, when turning ON the main switch 350, the drive circuit 200 turns ON the first switch 160, turns OFF the second switch 162, and sets power supply voltage output from the power supply section 170 to be the second power supply voltage. In this way, a circuit from the first voltage source 140 to the reference potential 120 is connected, and a constant current of 100 μA flows through this circuit. Accordingly, the drive circuit 200 outputs a first drive signal of −15 V, obtained by a shift of 5 V from the first power supply voltage, from the first output terminal 220. Furthermore, the drive circuit 200 outputs the second power supply voltage of 0 V from the second output terminal 222 as the second drive signal, since the second switch 162 is OFF.

When turning OFF the main switch 350, the drive circuit 200 turns OFF the first switch 160, turns ON the second switch 162, and sets the power supply voltage output from the power supply section 170 to be the third power supply voltage. In this way, a circuit from the power supply section 170 to the reference potential 120 is connected, and a constant current of 100 μA flows through this circuit. Accordingly, the drive circuit 200 outputs a second drive signal of −15 V, obtained by a shift of 8 V from the third power supply voltage of −7 V, from the second output terminal 222. Furthermore, the drive circuit 200 outputs the first power supply voltage of −10 V from the first output terminal 220 as the first drive signal, since the first switch 160 is OFF.

In this way, the drive circuit 200 can supply the switch section 300 with a first drive signal that switches between substantially −15 V and substantially −10 V and a second drive signal that switches between substantially 0 V and substantially −15 V. Furthermore, by switching the first switch 160 ON and OFF, switching the second switch 162 OFF and ON, and switching the output voltage of the power supply section 170, the drive circuit 200 can output the first drive signal and the second drive signal.

In other words, the control section 110 can output the first drive signal and the second drive signal from the drive circuit 200 by supplying the first switch 160 and the second switch 162 respectively with control signals having a potential difference of substantially 3 V or more therebetween and a control signal for switching the output voltage of the power supply section 170. The control section 110 is connected to the power supply section 170, the first switch 160, and the second switch 162. FIG. 3 shows an example in which the control section 110 is connected to the gate of the first switch 160 and the gate of the second switch 162.

The control section 110 may supply the first input terminal 210 with a control signal of substantially −16.5 V as the ON voltage for turning the first switch 160 ON and a control signal of substantially −19.5 V as the OFF voltage for turning OFF the first switch 160. The control section 110 may supply the second input terminal 212 with a control signal of substantially −16.5 V as the ON voltage for turning the second switch 162 ON and a control signal of substantially −19.5 V as the OFF voltage for turning OFF the first switch 160.

The control section 110 may supply the power supply section 170 with a control signal that causes the second power supply voltage to be output from the power supply section 170 and a control signal that causes the third power supply voltage to not be output from the power supply section 170, for example. The control section 110 may supply the power supply section 170 with a control signal that causes the second power supply voltage to not be output from the power supply section 170 and a control signal that causes the third power supply voltage to be output from the power supply section 170. In this way, the control section 110 can switch the voltage output from the power supply section 170.

Instead, the control section 110 may supply the power supply section 170 with a control signal that switches the output voltage from the power supply section 170 from the second power supply voltage to the third power supply voltage. Furthermore, the control section 110 may supply the power supply section 170 with a control signal that switches the output voltage from the power supply section 170 from the third power supply voltage to the second power supply voltage.

In the manner described above, the drive circuit 200 can supply the switch section 300 with the first drive signal and the second drive signal according to the control signal from the control section 110. Furthermore, since the power supply voltage output by the power supply section 170 is switched according to the voltage of the drive signal, the drive circuit 200 can prevent change in the power consumption.

In the example of FIG. 3, when the first switch 160 is ON, a current of 100 μA flows through the first resistor 150 of 50 kΩ. Furthermore, when the second switch 162 is ON, a current of 100 μA flows through the second resistor 152 of 80 kΩ, and therefore there is difference of only a factor of 1.6 in the power consumption.

In other words, when the absolute value of the potential difference between the first drive signal and the second drive signal decreases from 15 V to 5 V, the drive circuit 200 of the present embodiment reduces the power supply voltage output by the power supply section 170 from 0 V to −7 V. In this way, the drive circuit 200 can prevent the increase in power consumption corresponding to the potential difference in the drive signal.

The switch apparatus 100 of the present embodiment can be configured by a simple circuit using FETs with substantially the same configurations, and therefore this circuit can be easily manufactured. Furthermore, since the switching operation of the switches is performed by FETs, high-speed operation can be realized. Yet further, since the switch apparatus 100 can be configured using FETs having substantially the same configurations, the circuit can be formed easily with consideration paid only to manufacturing variation among a single FET configuration.

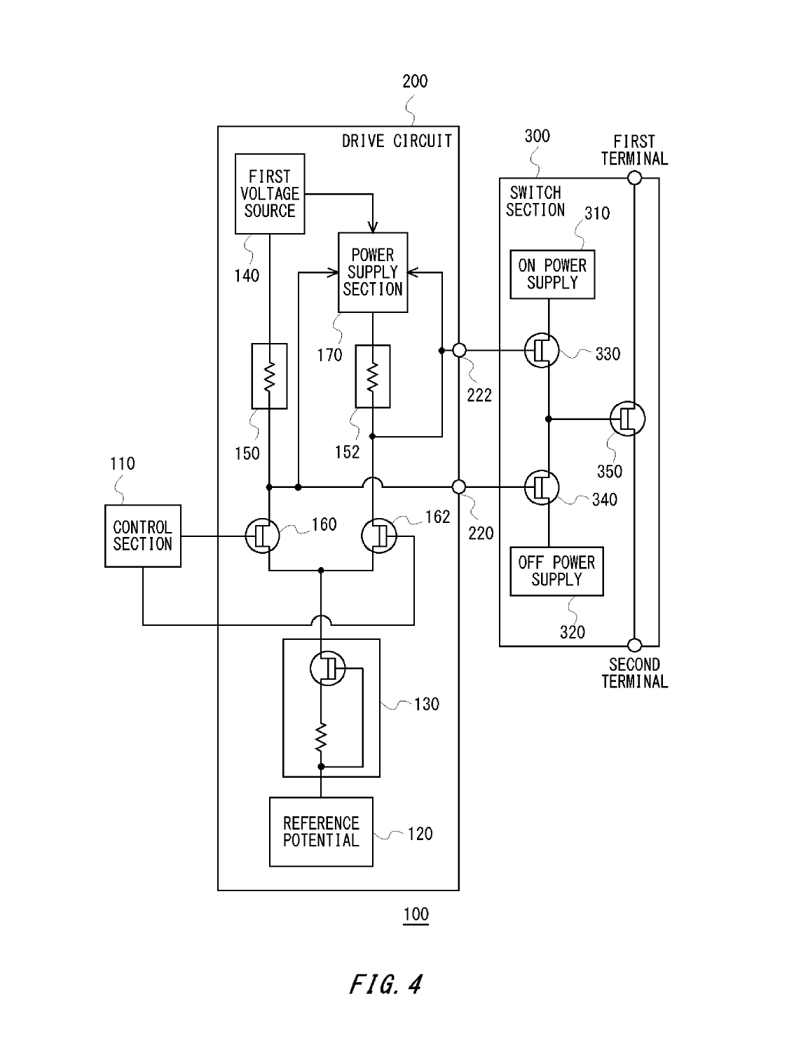

FIG. 4 shows a configuration of a modification of the switch apparatus 100 according to the present embodiment, along with the control section 110. In the switch apparatus 100 of the present modification, components that have substantially the same operation as components in the switch apparatus 100 shown in FIG. 3 are given the same reference numerals and redundant descriptions are omitted.

The drive circuit 200 of the switch apparatus 100 of the present modification changes the power supply voltage of the power supply section 170 according to an internally generated control signal. For example, the power supply section 170 is connected to the second output terminal 222 and switches whether the second power supply voltage is output by using the drive signal output from the second output terminal 222.

For example, when the second switch 162 is switched from OFF to ON, the drive circuit 200 outputs, as the drive signal, a voltage obtained by decreasing the power supply voltage of the power supply section 170 by a voltage equal to the product of the current flowing from the current source 130 and the resistance value of the second resistor 152. Accordingly, the power supply section 170 stops the output of the second power supply voltage in response to the voltage drop in the drive voltage from the second output terminal 222.

When the second switch 162 is switched from ON to OFF, the current flowing through the second resistor 152 is cut off, and therefore the drive circuit 200 outputs, as the drive signal, a voltage equal to the power supply voltage of the power supply section 170 that has been raised back up after the drop. Therefore, the power supply section 170 outputs the second power supply voltage as the power supply voltage in response to the voltage increase of the drive voltage from the second output terminal 222.

The power supply section 170 is connected to the first output terminal 220 and switches whether the third power supply voltage is output by using the drive signal output from the first output terminal 220. For example, when the first switch 160 is switched from OFF to ON, the drive circuit 200 outputs, as the drive signal, a voltage obtained by decreasing the power supply voltage of the power supply section 170 by a voltage equal to the product of the current flowing from the current source 130 and the resistance value of the first resistor 150. Accordingly, the power supply section 170 stops the output of the third power supply voltage in response to the voltage drop in the drive voltage from the first output terminal 220.

When the first switch 160 is switched from ON to OFF, the current flowing through the first resistor 150 is cut off, and therefore the drive circuit 200 outputs, as the drive signal, a voltage equal to the power supply voltage of the power supply section 170 that has been raised back up after the drop. Therefore, the power supply section 170 outputs the third power supply voltage as the power supply voltage in response to the voltage increase of the drive voltage from the first output terminal 220.

In this way, the drive circuit 200 can turn the main switch 350 ON by setting the power supply voltage output from the power supply section 170 to be the second power supply voltage, in response to the control signal for turning ON the first switch 160 and turning OFF the second switch 162. Furthermore, the drive circuit 200 can turn the main switch 350 OFF by setting the power supply voltage output from the power supply section 170 to be the third power supply voltage, in response to the control signal for turning OFF the first switch 160 and turning ON the second switch 162. In this way, the switch apparatus 100 of the present modification can reduce the number of control signals supplied to the control section 110, and can realize reduced circuit size and reduced power consumption.

The power supply section 170 of the drive circuit 200 of the present modification is connected to the first voltage source 140, receives the first power supply voltage supplied from the first voltage source 140, and outputs the third power supply voltage. In this case, the power supply section 170 may output the first power supply voltage as the third power supply voltage, for example. FIG. 4 shows an example in which the first power supply voltage and the third power supply voltage are each −10 V, the second power supply voltage is 0 V, and the resistance value of the second resistor 152 is 50 kΩ.

When turning ON the main switch 350, for example, the drive circuit 200 of the present modification turns ON the first switch 160 and turns OFF the second switch 162. In this way, a circuit from the first voltage source 140 to the reference potential 120 is connected, and a constant current of 100 μA flows through this circuit. Accordingly, the first output terminal 220 outputs a first drive signal of −15 V, obtained by a shift of 5 V from the first power supply voltage. The power supply section 170 sets the power supply voltage to the second power supply voltage of 0 V in response to this first drive signal. Since the second switch 162 is OFF, the second output terminal 222 outputs the second power supply voltage of 0 V as the second drive signal.

When turning OFF the main switch 350, the drive circuit 200 turns OFF the first switch 160 and turns ON the second switch 162. In this way, a circuit from the power supply section 170 to the reference potential 120 is formed, a constant current of 100 μA flows through this circuit, and the voltage output by the second output terminal 222 drops. As a result, the power supply section 170 sets the power supply voltage to be the third power supply voltage. Accordingly, the second output terminal 222 outputs a second drive signal of −15 V, obtained by a shift of 5 V from the third power supply voltage of −10 V. On the other hand, the first output terminal 220 outputs the first power supply voltage of −10 V as the first drive signal, since the first switch 160 is OFF.

In this way, the drive circuit 200 can supply the switch section 300 with a first drive signal that switches between substantially −15 V and substantially −10 V and a second drive signal that switches between substantially 0 V and substantially −15 V. Furthermore, by switching the first switch 160 ON and OFF, switching the second switch 162 OFF and ON, and switching the output voltage of the power supply section 170, the drive circuit 200 can output the first drive signal and the second drive signal. In other words, the control section 110 can output the first drive signal and the second drive signal from the drive circuit 200 by supplying the first switch 160 and the second switch 162 respectively with control signals having a potential difference greater than or equal to the threshold voltage Vth therebetween.

According to the modification of the present embodiment described above, the third power supply voltage and the first power supply voltage are made equal, and therefore the resistance values of the first resistor 150 and the second resistor 152 are substantially the same. In the example of FIG. 4 when the first switch 160 is ON, a current of 100 μA flows through the first resistor 150 of 50 kΩ. Furthermore, when the second switch 162 is ON, a current of 100 μA flows through the second resistor 152 of 50 kΩ, and therefore the change in power consumption is substantially zero.

In other words, the drive circuit 200 according to the modification of the present embodiment can stop the increase in power consumption corresponding to the voltage of the drive signal. Furthermore, the switch apparatus 100 of the present embodiment can be configured by a simple circuit using FETs with substantially the same configurations, and therefore the switch apparatus 100 can realize high-speed operation and low power consumption with a simple configuration.

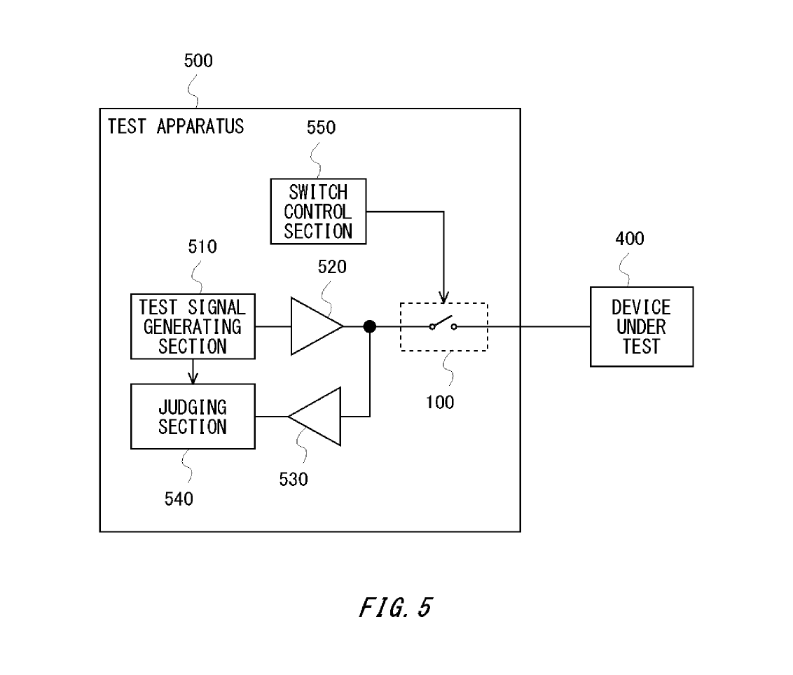

FIG. 5 shows an exemplary configuration of a test apparatus 500 according to the present embodiment, along with a device under test 400. The test apparatus 500 tests the device under test 400, which is an analog circuit, digital circuit, memory, system on chip (SOC), or the like. The test apparatus 500 inputs to the device under test 400 a test signal based on a test pattern for testing the device under test 400, and judges pass/fail of the device under test 400 based on the output signal output by the device under test 400 in response to the test signal.

The test apparatus 500 includes the switch apparatus 100, a test signal generating section 510, a driver 520, a comparator 530, a judging section 540, and a switch control section 550. The test signal generating section 510 generates the test signal for testing the device under test 400. The test signal generating section 510 generates an expected value for the response signal to be output by the device under test 400 in response the test signal, and transmits this expected value to the judging section 540.

The driver 520 is connected to the test signal generating section 510 and supplies the device under test 400 with the test signal generated by the test signal generating section 510. The comparator 530 acquires the logic value of the response signal output from the device under test 400 in response to the test signal being provided. The judging section 540 is connected to the comparator 530 and judges pass/fail of the device under test 400 by comparing the logic value acquired by the comparator 530 to the expected value received from the test signal generating section 510.

The switch apparatus 100 is provided between the test signal generating section 510 and the device under test 400. In the present embodiment, the switch apparatus 100 is provided between the driver 520 and the device under test 400. The switch apparatus 100 enables or disables the electrical connection between the test signal generating section 510 and the device under test 400, according to the voltage of a control signal supplied from the switch control section 550. The switch control section 550 causes the switch apparatus 100 to enable the electrical connection when testing of the test apparatus 500 is performed, and causes the switch apparatus 100 to disable the electrical connection when the testing of the test apparatus 500 is stopped or suspended.

In this way, the test apparatus 500 can perform testing using the switch apparatus 100 that is configured of FETs with a small size, long lifespan, and high reliability and driven by the drive circuit 200 with low power consumption. The test apparatus 500 of the present embodiment is an example in which the test signal generating section 510 and the judging section 540 are connected to the device under test 400 through a single switch apparatus 100. Instead, a plurality of test signal generating sections 510 and judging sections 540 may be connected to a plurality of input/output sections of the device under test 400 via plurality of switch apparatuses 100.

Furthermore, this test apparatus 500 is an example in which a portion of the transmittion path of the test signal and a portion of the reception path of the test signal are shared. Instead, the test apparatus 500 may include a path that connects the test signal generating section 510 to the device under test 400 via one switch apparatus 100 and a path that connects the device under test 400 to the judging section 540 via another switch apparatus 100, such that the test signal transmission path and the response signal reception path are separated from each other.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A drive circuit comprising:
a current source having one end thereof connected to a reference potential;
a first switch connected between the current source and a first voltage source that outputs a first power supply voltage;
a first output terminal that outputs a voltage between the first switch and the first voltage source;
a power supply section that outputs a second power supply voltage when the first switch is ON and outputs a third power supply voltage, which is lower than the second power supply voltage, when the first switch is OFF;
a second switch connected between the power supply section and the current source; and
a second output terminal that outputs a voltage between the second switch and the power supply section.

2. The drive circuit according to claim 1, wherein
the power supply section outputs, as the second power supply voltage, a voltage that is higher than the first power supply voltage.

3. The drive circuit according to claim 1, wherein
the power supply section receives the first power supply voltage supplied from the first voltage source and outputs the third power supply voltage.

4. The drive circuit according to claim 1, wherein
the power supply section outputs, as the third power supply voltage, a voltage that is greater than or equal to the first power supply voltage.

5. The drive circuit according to claim 1, wherein
the power supply section is connected to the first output terminal and switches whether the third power supply voltage is output by using a drive signal output from the first output terminal.

6. The drive circuit according to claim 1, wherein
the power supply section is connected to the second output terminal and switches whether the second power supply voltage is output by using a drive signal output from the second output terminal.

7. The drive circuit according to claim 1, comprising a first resistor connected between the first voltage source and the first switch, wherein
the first output terminal outputs a first power supply voltage from the first voltage source when the first switch is OFF, and outputs a voltage obtained by subtracting a voltage drop determined by the first resistor and current flowing from the current source from the first power supply voltage when the first switch is ON.

8. The drive circuit according to claim 1, comprising a second resistor connected between the power supply section and the second switch, wherein
the second output terminal outputs the second power supply voltage when the second switch is OFF, and outputs a voltage obtained by subtracting a voltage drop determined by the second resistor and current flowing from the current source from the second power supply voltage when the second switch is ON.

9. A switch apparatus that provides an electrical connection or disconnection between a first terminal and a second terminal, comprising:
the drive circuit according to claim 1; and
a main switch that is turned ON and OFF according to a first drive signal output from the first output terminal of the drive circuit and a second drive signal output from the second output terminal of the drive circuit.

10. The switch apparatus according to claim 9, further comprising:
an ON switch that has a gate supplied with the second drive signal and is electrically connected between a gate of the main switch and an ON power supply for turning ON the main switch; and
an OFF switch that has a gate supplied with the first drive signal and is electrically connected between a gate of the main switch and an OFF power supply for turning OFF the main switch, wherein
when turning ON the main switch, the drive circuit turns ON the ON switch and turns OFF the OFF switch, and
when turning OFF the main switch, the drive circuit turns OFF the ON switch and turns ON the OFF switch.

11. A test apparatus that tests a device under test, comprising:
a test signal generating section that generates a test signal for testing the device under test; and
the switch apparatus according to claim 9 that is provided between the test signal generating section and the device under test and causes conduction or a disconnection between the test signal generating section and the device under test.
